(19) United States
(12) Patent Application Publication
(10) Pub. No.: US 2015/0075604 A1
(43) Pub. Date: Mar. 19, 2015

(54) THIN-FILM COMPOUND PHOTOVOLTAIC CELL AND METHOD FOR MANUFACTURING SAME

(71) Applicant: Sharp Kabushiki Kaisha, Osaka-shi, Osaka (JP)

(72) Inventor: Hiroshi Yamaguchi, Osaka-shi (JP)

(21) Appl. No.: 14/387,017

(22) PCT Filed: Mar. 21, 2013
(86) PCT No.: PCT/JP2013/058008

§ 371 Date: Sep. 22, 2014

(30) Foreign Application Priority Data
Mar. 21, 2012 (JP) 2012-063605

(51) Int. Cl. H01L 31/0352; H01L 31/0224

(52) U.S. Cl. CPC H01L 31/035281; H01L 31/022425
USPC 136/256; 438/68

(57) ABSTRACT

A base material formed of a thin film, a rear surface electrode located on the base material, a photoelectric conversion layer located on the rear surface electrode, a first surface electrode that is located above the rear surface electrode, is electrically connected to the rear surface electrode, and has a first polarity, and a second surface electrode that is located on the photoelectric conversion layer and has a second polarity different from the first polarity are included. The edge of the base material is located outside the edge of the rear surface electrode with space left therebetween and surrounds the entire perimeter of the rear surface electrode in plan view.

### TECHNICAL FIELD

The present invention relates to a thin-film compound photovoltaic cell and a method for manufacturing the thin-film compound photovoltaic cell.

### BACKGROUND ART

As a prior literature that discloses a method for manufacturing a thin-film compound photovoltaic cell, there is International Publication No. 2010-098293 Pamphlet (PTL 1). In a thin-film compound photovoltaic cell manufactured by the thin-film compound photovoltaic cell manufacturing method described in PTL 1, a rear surface electrode, a photoelectric conversion layer, and a surface electrode are formed on a base material formed of film polyimide.

Moreover, as a prior literature that discloses the configuration of a photovoltaic cell array, there is Japanese Unexamined Patent Application Publication No. 2009-44049 (PTL 2). A photovoltaic cell array described in PTL 2 includes a first electrode having a first polarity, the first electrode formed on a light receiving surface of a semiconductor single-crystalline layer with at least one pn junction, and a second electrode having a second polarity, the second electrode formed on a surface on the side of the semiconductor single-crystalline layer where the light receiving surface is located, the surface which is different from the surface on which the first electrode is formed. Of a plurality of photovoltaic cells, the first electrode of a first photovoltaic cell and the second electrode of a second photovoltaic cell are connected to each other by an interconnector.

### CITATION LIST

### Patent Literature

PTL 1: International Publication No. 2010-098293 Pamphlet

PTL 2: Japanese Unexamined Patent Application Publication No. 2009-44049

### SUMMARY OF INVENTION

### Technical Problem

A separated photovoltaic cell of a thin-film compound photovoltaic cell is obtained by performing cutting between a plurality of photoelectric conversion layers with a Thomson blade, the plurality of photoelectric conversion layers formed on a base material at intervals. Since a rear surface electrode is formed all over the base material, when photovoltaic cells are separated from each other, the base material and the rear surface electrode are cut together with the Thomson blade.

At the edge of the separated photovoltaic cell obtained as described above, a thread-like portion which is an imperfect cut portion sometimes appears. This thread-like portion is formed of part of the base material and part of the rear surface electrode. If a photovoltaic cell array is configured by connecting a photovoltaic cell with a thread-like portion to another photovoltaic cell by an interconnector, a short circuit sometimes occurs by part of the rear surface electrode included in the thread-like portion, causing a reduction in the output of the photovoltaic cell array.

The present invention has been made in view of the problems described above, and an object thereof is to provide a thin-film compound photovoltaic cell and a method for manufacturing the thin-film compound photovoltaic cell, the thin-film compound photovoltaic cell and the method that can prevent the occurrence of a short circuit by a thread-like portion and produce a stable output.

### Solution to Problem

A thin-film compound photovoltaic cell based on the present invention includes a base material formed of a thin film, a rear surface electrode located on the base material, a photoelectric conversion layer located on the rear surface electrode, a first surface electrode that is located above the rear surface electrode, is electrically connected to the rear surface electrode, and has a first polarity, and a second surface electrode that is located on the photoelectric conversion layer and has a second polarity different from the first polarity. The edge of the base material is located outside the edge of the rear surface electrode with space left therebetween and surrounds an entire perimeter of the rear surface electrode in plan view.

In an aspect of the present invention, the edge of the base material is formed of a cut surface.

In an aspect of the present invention, the edge of the rear surface electrode is formed of an etched surface of the rear surface electrode on which a material thereof is etched and exposed or a depositional surface on which the material of the rear surface electrode is evaporated and deposited.

In an aspect of the present invention, the base material is formed of a film resin.

In an aspect of the present invention, the resin is polyimide.

In an aspect of the present invention, the cut surface is a cut surface formed by cutting performed by a Thomson blade.

A method for manufacturing a thin-film compound photovoltaic cell based on the present invention includes a process of forming a photoelectric conversion layer on a substrate, a process of forming, on the photoelectric conversion layer, a rear surface electrode on which patterning has been performed to have a groove, a process of forming a base material formed of a thin film on the rear surface electrode on which patterning has been performed, a process of removing the substrate after the process of forming the base material, a process of forming a first surface electrode being electrically connected to the rear surface electrode and having a first polarity on the side where the photoelectric conversion layer is located when viewed from the rear surface electrode after the process of removing the substrate, a process of forming a second surface electrode having a second polarity different from the first polarity on the side opposite to the side of the photoelectric conversion layer where the rear surface electrode is located after the process of forming the first surface electrode, and a process of performing cutting in the position of the groove after the process of forming the second surface electrode.

In an aspect of the present invention, in the cutting process, cutting is performed by pressing a Thomson blade against the position of the groove.

In an aspect of the present invention, the process of forming the rear surface electrode on which patterning has been performed to have the groove includes a process of forming the rear surface electrode on the photoelectric conversion layer and a process of forming a resist on the rear surface electrode and performing etching.

In an aspect of the present invention, the process of forming the rear surface electrode on which patterning has been performed to have the groove includes a process of forming a resist in a position in which the groove has to be formed on the photoelectric conversion layer, a process of evaporating a material of the rear surface electrode on the photoelectric conversion layer and the resist, and a process of removing both the resist and the material of the rear surface electrode, the material evaporated on the resist.

### Advantageous Effects of Invention

According to the present invention, it is possible to prevent a short circuit from occurring by a thread-like portion and produce a stable output.

### BRIEF DESCRIPTION OF DRAWINGS

FIG. 1 is a partial sectional view depicting the configuration of a photovoltaic cell array including a thin-film compound photovoltaic cell according to an embodiment of the present invention.

FIG. 2 is a sectional view of FIG. 1 viewed from a II-II line arrow direction.

FIG. 3 is a sectional view depicting a state in which compound semiconductor layers are formed on a substrate.

FIG. 4 is a sectional view depicting a state in which a rear surface electrode is formed on the compound semiconductor layers.

FIG. 5 is a sectional view depicting a state in which a resist is formed on the rear surface electrode.

FIG. 6 is a sectional view depicting a state in which the rear surface electrode is etched.

FIG. 7 is a sectional view depicting a state in which a base material is provided on the rear surface electrode.

FIG. 8 is a sectional view depicting a state in which a reinforcing material is pasted on the base material.

FIG. 9 is a sectional view depicting a state in which the substrate is removed by etching.

FIG. 10 is a sectional view depicting a state in which an etching-stop layer is removed by etching.

FIG. 11 is a sectional view depicting a state in which a resist is formed on a contact layer.

FIG. 12 is a sectional view depicting a state in which the compound semiconductor layers are etched.

FIG. 13 is a sectional view depicting a state in which an electrode material which will become a first surface electrode is provided.

FIG. 14 is a sectional view depicting a state in which the first surface electrode is formed.

FIG. 15 is a sectional view depicting a state in which a resist is formed on part of an area on the contact layer and on the first surface electrode.

FIG. 16 is a sectional view depicting a state in which the contact layer is etched.

FIG. 17 is a sectional view depicting a state in which the resist is removed.

FIG. 18 is a sectional view depicting a state in which a resist is formed in a position other than an area on the contact layer.

FIG. 19 is a sectional view depicting a state in which an electrode material which will become a second surface electrode is provided.

FIG. 20 is a sectional view depicting a state in which the second surface electrode is formed.

FIG. 21 is a sectional view in which the reinforcing material is removed.

FIG. 22 is a sectional view depicting a state in which a resist is formed on the compound semiconductor layers.

FIG. 23 is a sectional view depicting a state in which an electrode material which will become a rear surface electrode is provided.

FIG. 24 is a plan view depicting the structure of a plurality of thin-film compound photovoltaic cells which are not yet separated from each other.

FIG. 25 is a sectional view depicting a state in which a Thomson blade is pressed.

FIG. 26 is a plan view depicting the structure of a separated photovoltaic cell of a thin-film compound photovoltaic cell.

### DESCRIPTION OF EMBODIMENTS

Hereinafter, a thin-film compound photovoltaic cell and a method for manufacturing the thin-film compound photovoltaic cell, the thin-film compound photovoltaic cell and the method according to an embodiment of the present invention, will be described. In the following description of the embodiment, identical or equivalent parts in the drawings are identified with the same characters, and their descriptions are not repeated.

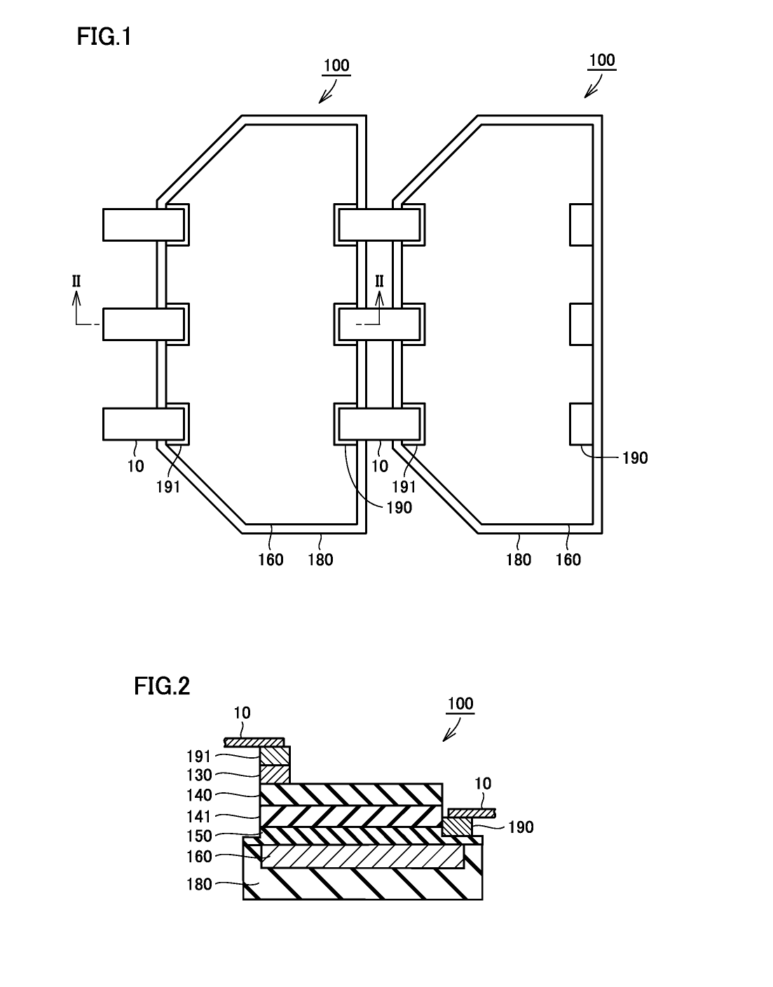

FIG. 1 is a partial sectional view depicting the configuration of a photovoltaic cell array including a thin-film compound photovoltaic cell according to the embodiment of the present invention. FIG. 2 is a sectional view of FIG. 1 viewed from a II-II line arrow direction. Incidentally, in FIG. 1, a photoelectric conversion layer is not depicted.

As depicted in FIGS. 1 and 2, a photovoltaic cell 100 of the thin-film compound photovoltaic cell according to the embodiment of the present invention includes a base material 180, a rear surface electrode 160 located on the base material 180, and a photoelectric conversion layer located on the rear surface electrode 160. The photoelectric conversion layer includes a first contact layer 130, an emitter layer 140, a base layer 141, and a second contact layer 150 which will be described later.

Moreover, the photovoltaic cell 100 includes a first surface electrode 190 that is located above the rear surface electrode 160, is electrically connected to the rear surface electrode 160, and has a first polarity and a second surface electrode 191 that is located on the photoelectric conversion layer and has a second polarity different from the first polarity. In this embodiment, the first polarity is a p-type and the second polarity is an n-type. However, the first polarity may be an n-type and the second polarity may be a p-type.

The base material 180 has a hexagonal outer shape in plan view. However, the outer shape of the base material 180 is not limited to a hexagon and may be a rectangle, a circle, or the like. The rear surface electrode 160 also has a hexagonal outer shape in plan view. However, the outer shape of the rear surface electrode 160 is not limited to a hexagon and may be a rectangle, a circle, or the like.

In plan view, the edge of the base material 180 is located outside the edge of the rear surface electrode 160 with space left therebetween and surrounds the entire perimeter of the rear surface electrode 160. That is, in plan view, the edge of the rear surface electrode 160 is located inside the edge of the base material 180.

In the photovoltaic cell array, as a result of the first surface electrode 190 of one of the photovoltaic cells 100 disposed so as to be adjacent to each other and the second surface electrode 191 of the other of the photovoltaic cells 100 being electrically connected to each other by an interconnector 10, a plurality of photovoltaic cells 100 are connected in series.

Hereinafter, a method for manufacturing the photovoltaic cell 100 of the thin-film compound photovoltaic cell will be described.

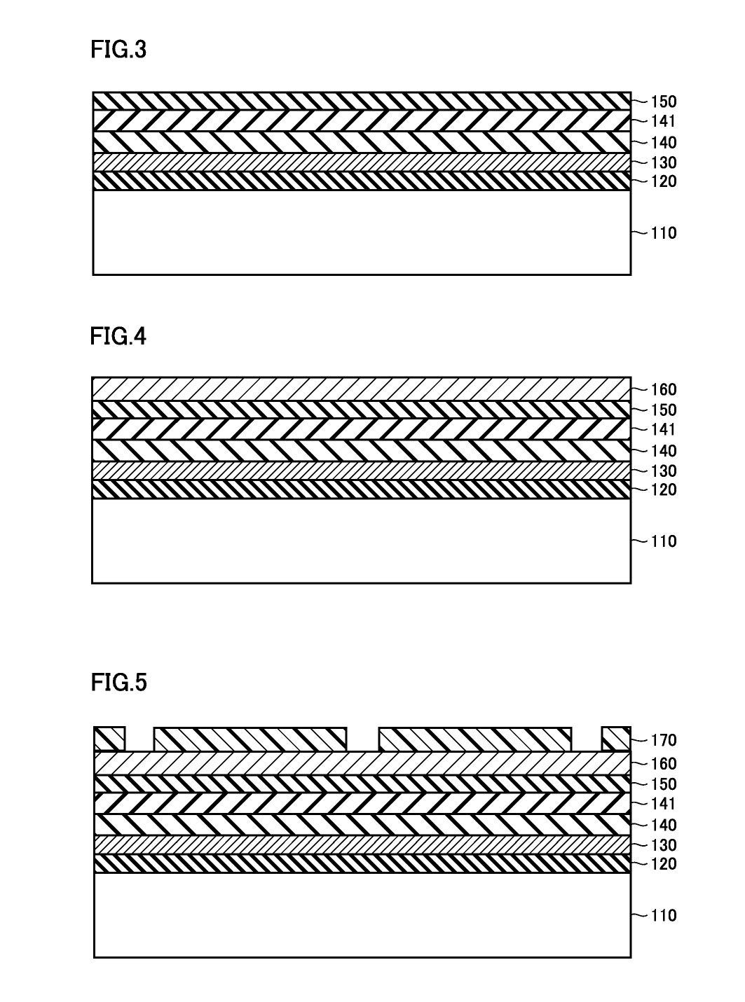

FIG. 3 is a sectional view depicting a state in which compound semiconductor layers are formed on a substrate. As depicted in FIG. 3, by stacking an etching-stop layer 120, the first contact layer 130, the emitter layer 140 formed of a first compound semiconductor, a base layer 141 forming a pn junction with the emitter layer 140, and the second contact layer 150 on the substrate 110 in this order, the compound semiconductor layers formed of single-crystalline thin films are formed. Incidentally, the etching-stop layer 120 is a layer that serves as an etching stopper for a first etching solution that etches the substrate 110.

The substrate 110 has a wafer-like form, for example. The compound semiconductor layers including the etching-stop layer 120, the first contact layer 130, the emitter layer 140, the base layer 141, and the second contact layer 150 can be stacked by epitaxial growth by metallorganic vapor deposition or the like.

Specifically, as the material of the substrate 110, Ge, GaP, GaAs, or the like can be used. As the material of the etching-stop layer 120, InGaP can be used. As the material of the first contact layer 130, GaAs can be used. As the material of the emitter layer 140, n-type InGaP can be used. As the material of the base layer 141, p-type InGaP can be used. As the material of the second contact layer 150, GaAs can be used.

Incidentally, in this embodiment, the compound semiconductor layers are configured to have a five-layered structure, but the number of stacked compound semiconductor layers is not limited to five and may be four or six. Moreover, the compound semiconductor layers may include a back surface field layer, a window layer, a tunnel junction layer of a multi-junction type photovoltaic cell, other emitter layers or other base layers of the multi-junction type photovoltaic cell, and so forth.

That is, the compound semiconductor layers simply have to include at least one pn junction. Moreover, the compound semiconductor layers simply have to include a layer that is easily etched by a second etching solution etching at least the first contact layer 130 and is not easily etched by a third etching solution for mesa-etching and a layer that is not easily etched by the second etching solution and is easily etched by the third etching solution. The former layer corresponds to the first contact layer 130, and the latter layer corresponds to the emitter layer 140 and the base layer 141.

FIG. 4 is a sectional view depicting a state in which the rear surface electrode is formed on the compound semiconductor layers. As depicted in FIG. 4, the rear surface electrode 160 is formed on the second contact layer 150. The rear surface electrode 160 is formed by applying a metal paste such as Al or Ag over the entire upper surface of the second contact layer 150 by screen printing and then performing baking by performing heat treatment. Alternatively, the rear surface electrode 160 may be formed by evaporating an electrode material such as Al or Ag.

By forming the rear surface electrode 160 in this manner, it is possible to reduce the contact resistance between the surface of the compound semiconductor layers and the rear surface electrode 160 and increase the adhesive force between surface of the compound semiconductor layers and the rear surface electrode 160.

FIG. 5 is a sectional view depicting a state in which a resist is formed on the rear surface electrode. As depicted in FIG. 5, a resist 170 on which patterning has been performed by using photolithography is formed on the rear surface electrode 160.

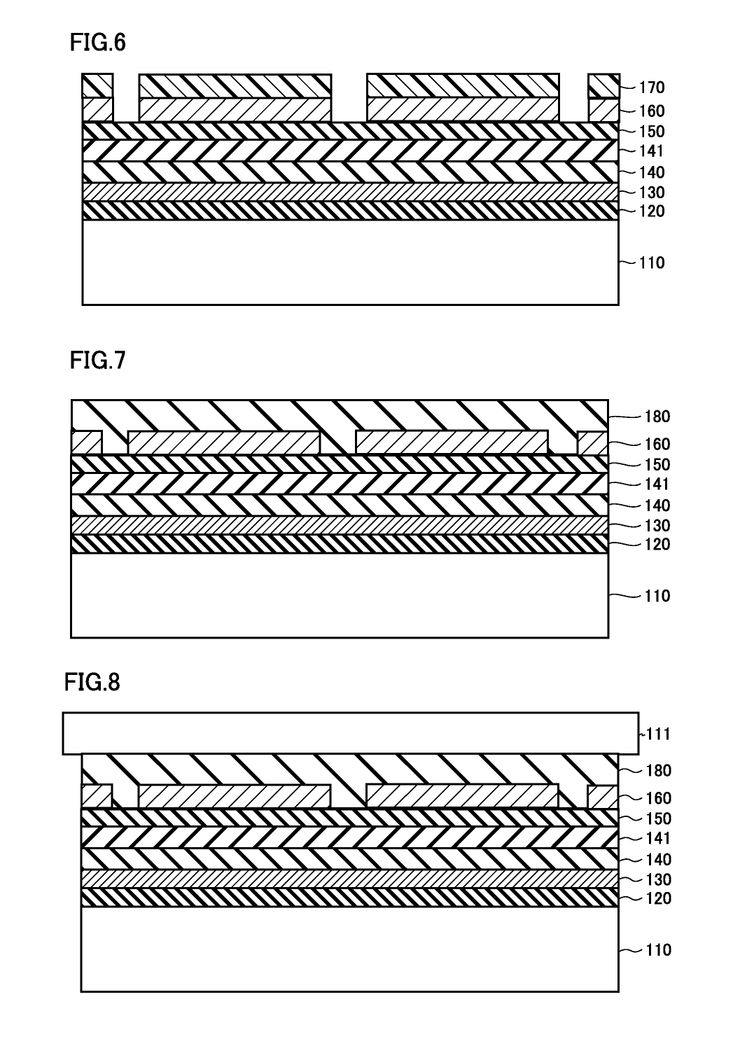

FIG. 6 is a sectional view depicting a state in which the rear surface electrode is etched. As depicted in FIG. 6, by performing etching in a state in which the resist 170 is formed, the rear surface electrode 160 in a portion which is not covered by the resist 170 is removed. As described above, patterning is performed on the rear surface electrode 160 in such a way that the rear surface electrode 160 has a groove. In this groove portion, the rear surface electrode 160 does not exist and the photoelectric conversion layer is exposed. Then, the resist 170 is removed.

FIG. 7 is a sectional view depicting a state in which the base material is provided on the rear surface electrode. As depicted in FIG. 7, as depicted in FIG. 7, the base material 180 is provided in such a way as to cover the entire upper surface of the rear surface electrode 160. In this embodiment, the base material 180 is formed of film resin.

As the resin, a material which can resist a temperature of 300° C. or higher can be used and, in this embodiment, polyimide is used. The base material 180 is formed by applying varnish-like resin over the entire upper surface of the rear surface electrode 160 at room temperature by spin coating or the like and then performing baking.

When the base material 180 is formed by applying polyimide varnish and then performing baking, it is necessary to control the film thickness of polyimide. The reason is that, if the film thickness of polyimide is 20 μm or more, it becomes impossible to form a flat film by baking due to air bubbles mixed into the polyimide film and cause damage to the compound semiconductor layers due to large warpage in the polyimide film.

When the film thickness of polyimide is reduced, in the range of 20 μm or less, the mixture of air bubbles is stopped and the warpage of the film is reduced. When the film thickness of polyimide is about 7 μm, the amount of warpage becomes the smallest, and, when the film thickness becomes less than 7 μm, the direction of warpage is reversed and the amount of warpage is increased again.

Therefore, with consideration given to the amount of warpage of polyimide and the elasticity thereof as a base material, as the film thickness of polyimide, the range of 5 to 15 μm is suitable and, in particular, a film thickness of about 7 μm is preferable.

Incidentally, in this embodiment, the base material 180 is formed by baking the varnish-like polyimide, but the method for forming the base material 180 is not limited thereto, and a method by which a thermal fusion adhesive film is pressed-fitted while being heated may be used.

As a result of the base material 180 being formed by the above-described method, the base material 180 functions as a base of a thin-film photovoltaic cell. Moreover, by setting the film thickness of the base material 180 at 15 μm or less, it is possible to reduce the warpage of the whole thin-film photovoltaic cell with a reduction in the warpage of the base material 180.

FIG. 8 is a sectional view depicting a state in which a reinforcing material is pasted on the base material. A reinforcing material 111 is a member that reinforces the compound semiconductor layers in the manufacturing process. As the reinforcing material 111, for example, a polyethylene terephthalate (PET) film with one surface to which an adhesive material whose adhesive strength is reduced when being irradiated with ultraviolet light is applied can be used.

By bringing the surface of the PET film to which the adhesive material is applied and the upper surface of the base material 180 into contact with each other, as depicted in FIG. 8, the reinforcing material 111 can be attached to the base material 180.

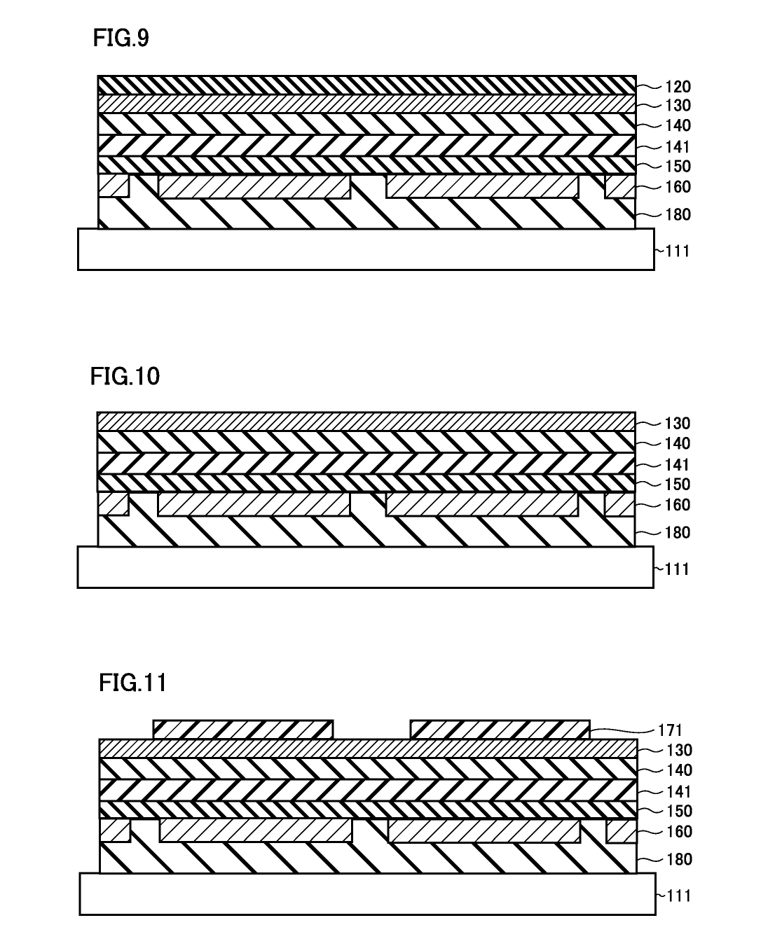

FIG. 9 is a sectional view depicting a state in which the substrate is removed by etching. As depicted in FIG. 9, after attaching the reinforcing material 111, the substrate 110 is removed by etching by using the first etching solution.

As the first etching solution, although different first etching solutions are used depending on the type of the substrate 110; if the substrate 110 is formed of Ge, a solution containing hydrofluoric acid, hydrogen peroxide water, and water in proportions of 1:1:4 is used.

When etching is performed by using the first etching solution, since the etching-stop layer 120 is a layer that is not easily etched by the first etching solution, the progress of etching is stopped when the substrate 110 is etched and the etching-stop layer 120 is exposed. This makes it possible to remove only the substrate 110 while leaving only the compound semiconductor layers.

FIG. 10 is a sectional view depicting a state in which the etching-stop layer is removed by etching. As depicted in FIG. 10, after the substrate 110 is removed, the etching-stop layer 120 is removed by using the second etching solution. As a result, the upper surface of the first contact layer 130 is exposed.

FIG. 11 is a sectional view depicting a state in which a resist is formed on the contact layer. As depicted in FIG. 11, a resist 171 on which patterning has been performed by using photolithography is formed on the first contact layer 130.

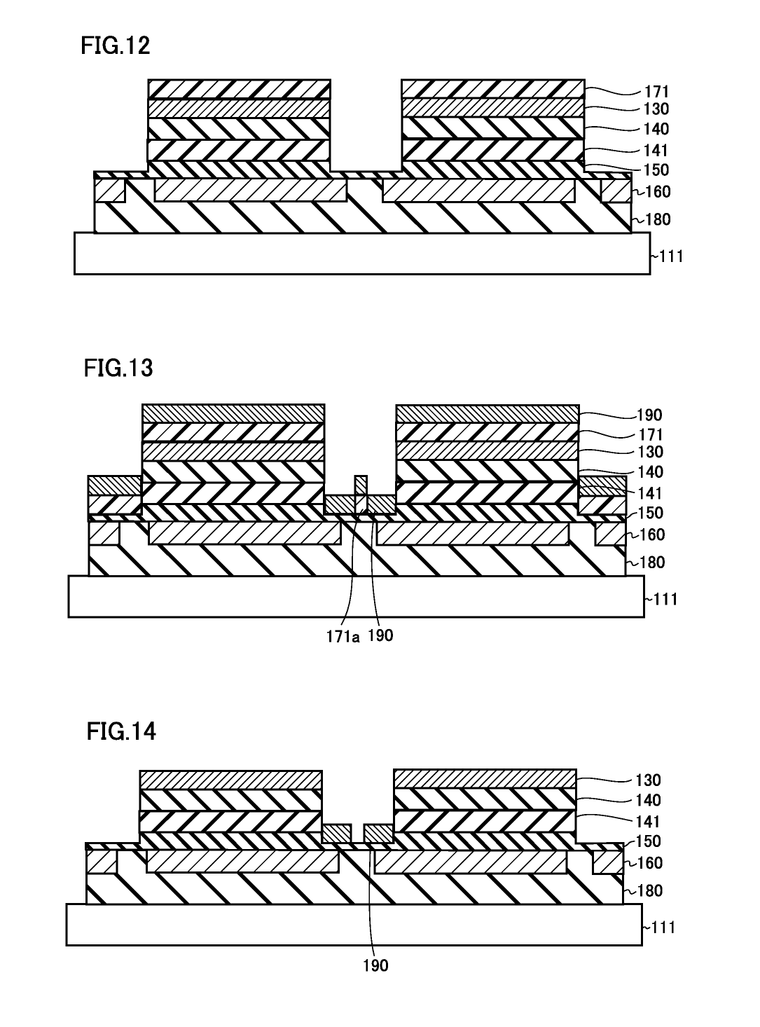

FIG. 12 is a sectional view depicting a state in which the compound semiconductor layers are etched. As depicted in FIG. 12, by performing etching in a state in which the resist 171 is formed, the compound semiconductor layers in a portion which is not covered by the resist 171 are removed. In this embodiment, etching is stopped when the second contact layer 150 is slightly left. However, etching may be performed until the upper surface of the rear surface electrode 160 is exposed.

FIG. 13 is a sectional view depicting a state in which an electrode material which will become the first surface electrode is provided. As depicted in FIG. 13, after the compound semiconductor layers are etched, a resist 171a is formed on part of an area on the second contact layer 150 exposed as a result of etching. Then, an electrode material is provided on the resists 171 and 171a and the second contact layer 150. In this embodiment, an electrode material such as Al or Ag is evaporated, but the electrode material may be applied by screen printing, for example.

FIG. 14 is a sectional view depicting a state in which the first surface electrode is formed. The compound semiconductor layers on which the electrode material is deposited are immersed in an organic solvent such as acetone. Then, the resists 171 and 171a dissolve in the organic solvent, and the electrode material deposited on the resists 171 and 171a is removed with the resists 171 and 171a.

As a result, as depicted in FIG. 14, the electrode material is selectively deposited only on the second contact layer 150 and the first surface electrode 190 is formed. That is, on the side where the photoelectric conversion layer is located when viewed from the rear surface electrode 160, the first surface electrode 190 that is electrically connected to the rear surface electrode 160 and has the first polarity is formed. Since the first surface electrode 190 is electrically connected to the base layer 141 via the rear surface electrode 160, the first surface electrode 190 is a p-type electrode.

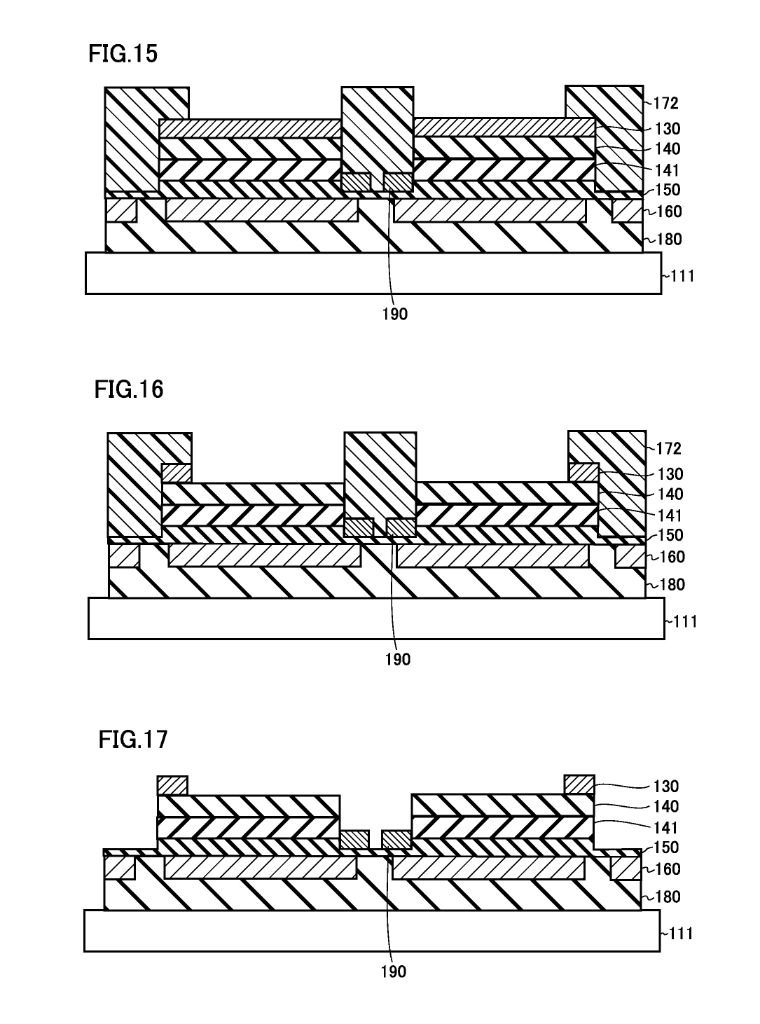

FIG. 15 is a sectional view depicting a state in which a resist is formed on part of an area on the contact layer and on the first surface electrode. As depicted in FIG. 15, a resist 172 on which patterning has been performed by using photolithography is formed on part of an area on the first contact layer 130 and on the first surface electrode 190.

FIG. 16 is a sectional view depicting a state in which the contact layer is etched. As depicted in FIG. 16, by performing etching in a state in which the resist 172 is formed, the first contact layer 130 in a portion which is not covered by the resist 172 is removed. As an etching solution, an alkali solution can be used. Part of the first contact layer 130 is removed, and part of the upper surface of the emitter layer 140 is exposed.

FIG. 17 is a sectional view depicting a state in which the resist is removed. As depicted in FIG. 17, by removing the resist 172, the first contact layer 130 on which patterning has been performed appears.

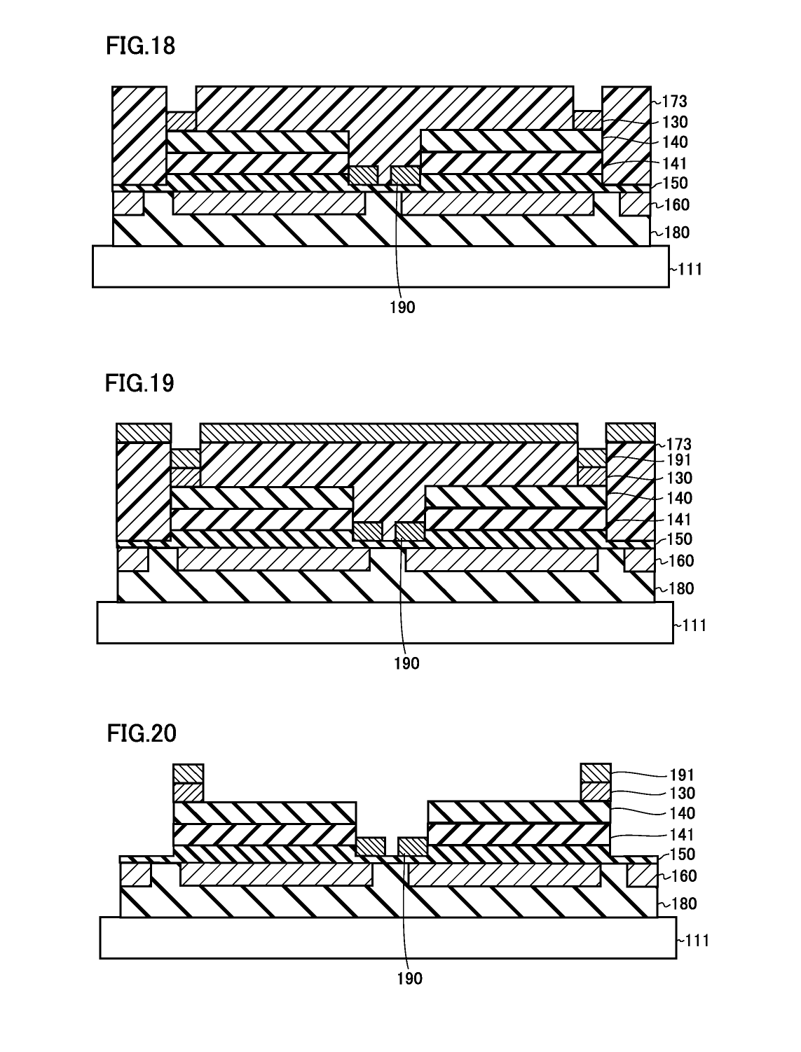

FIG. 18 is a sectional view depicting a state in which a resist is formed in a position other than an area on the contact layer. As depicted in FIG. 18, a resist 173 on which patterning has been performed by using photolithography is formed in a position other than an area on the first contact layer 130.

FIG. 19 is a sectional view depicting a state in which an electrode material which will become the second surface electrode is provided. As depicted in FIG. 19, an electrode material is provided on the resist 173. In this embodiment, an electrode material such as Al or Ag is evaporated, but the electrode material may be applied by screen printing, for example.

FIG. 20 is a sectional view depicting a state in which the second surface electrode is formed. The photoelectric conversion layer on which the electrode material is deposited is immersed in an organic solvent such as acetone. Then, the resist 173 dissolves in the organic solvent, and the electrode material deposited on the resist 173 is removed with the resist 173.

As a result, as depicted in FIG. 20, the electrode material is selectively deposited only on the first contact layer 130 and the second surface electrode 191 is formed. That is, the second surface electrode 191 having the second polarity different from the first polarity is formed on the side opposite to the side of the photoelectric conversion layer where the rear surface electrode 160 is located. Since the second surface electrode 191 is in contact with the emitter layer 140, the second surface electrode 191 is an n-type electrode.

Then, an unillustrated resist on which patterning has been performed to have an opening to define a region of a photovoltaic cell element is formed on the emitter layer 140. Next, mesa-etching is performed by immersing the photoelectric conversion layer in the third etching solution that can etch the photoelectric conversion layer.

The third etching solution is formed of an alkali solution and an acid solution. By mesa-etching, it is possible to define a photovoltaic cell element region.

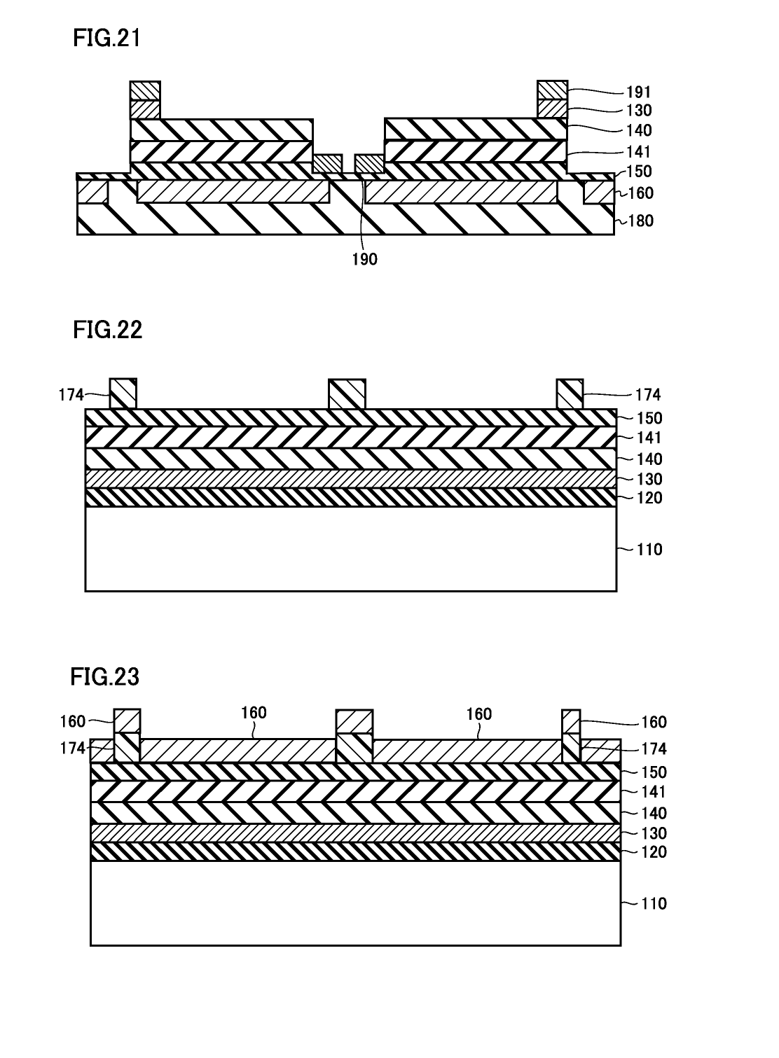

FIG. 21 is a sectional view depicting a state in which the reinforcing material is removed. As depicted in FIG. 21, the reinforcing material 111 is removed from the thin-film compound photovoltaic cell. As a method of removal, when an ultraviolet cure material is used as the adhesive material, the reinforcing material 111 is removed by reducing the adhesive force of the adhesive material by irradiating the reinforcing material 111 with ultraviolet light by an ultraviolet light irradiating apparatus.

After the removal of the reinforcing material 111, the first surface electrode 190 and the second surface electrode 191 are baked. By performing heat treatment, it is possible to reduce the contact resistance between the first surface electrode 190 and the second contact layer 150 and the contact resistance between the second surface electrode 191 and the first contact layer 130. Moreover, it is possible to improve the adhesion between the first surface electrode 190 and the second contact layer 150 and the adhesion between the second surface electrode 191 and the first contact layer 130.

By the above-described method, it is possible to fabricate the photovoltaic cell 100 of the thin-film compound photovoltaic cell. Incidentally, in the above-described method for manufacturing the thin-film compound photovoltaic cell, in the process of forming the groove in the rear surface electrode 160, the resist is formed on the rear surface electrode 160 and etching is performed, but the groove may be formed by a so-called liftoff process.

Hereinafter, a modified example using the liftoff process will be described.

FIG. 22 is a sectional view depicting a state in which a resist is formed on the compound semiconductor layers. From the state depicted in FIG. 3, as depicted in FIG. 22, before the rear surface electrode 160 is formed, a resist 174 on which patterning has been performed by using photolithography is formed on part of an area on the second contact layer 150.

FIG. 23 is a sectional view depicting a state in which an electrode material which will become the rear surface electrode is provided. As depicted in FIG. 23, after the resist 174 is formed, an electrode material is provided on the resist 174 and the second contact layer 150. In the modified example, an electrode material such as Al or Ag is evaporated.

The compound semiconductor layers on which the electrode material is deposited are immersed in an organic solvent such as acetone. Then, the resist 174 dissolves in the organic solvent, and the electrode material deposited on the resist 174 is removed with the resist 174. As a result, as depicted in FIG. 6, it is possible to perform patterning on the rear surface electrode 160 in such a way that the rear surface electrode 160 has a groove. In this groove portion, the rear surface electrode 160 does not exist and the photoelectric conversion layer is exposed.

That is, in the modified example, the process of forming the rear surface electrode 160 includes a process of forming the resist 174 in a position on the photoelectric conversion layer in which a groove has to be formed and a process of evaporating the material of the rear surface electrode 160 on the resist 174, and, in the process of forming the groove, both the resist 174 and the material of the rear surface electrode 160 evaporated on the resist 174 are removed.

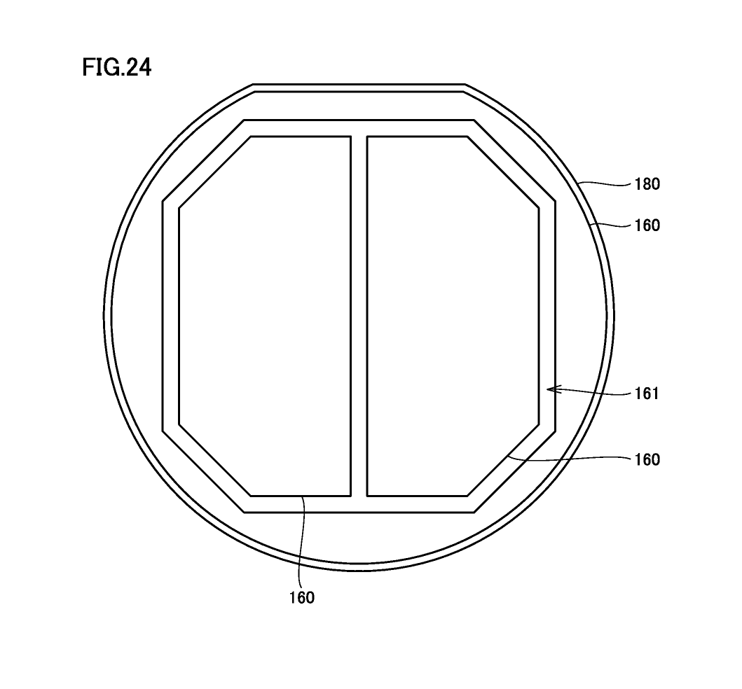

FIG. 24 is a plan view depicting the structure of a plurality of thin-film compound photovoltaic cells which are not yet separated from each other. Incidentally, in FIG. 24, the photoelectric conversion layer and the first and second surface electrodes 190 and 191 are not depicted.

As depicted in FIG. 24, patterning has been performed on the rear surface electrode 160 and a groove 161 is formed. The groove 161 is formed at the outer edge of the photovoltaic cell element region defined by mesa-etching. To obtain a separated photovoltaic cell 100 of the thin-film compound photovoltaic cell, a Thomson blade is pressed against the position of the groove 161. In the position of the groove 161, the rear surface electrode 160 does not exist. That is, cutting is performed in the position of the groove 161 in which the rear surface electrode 160 does not exist.

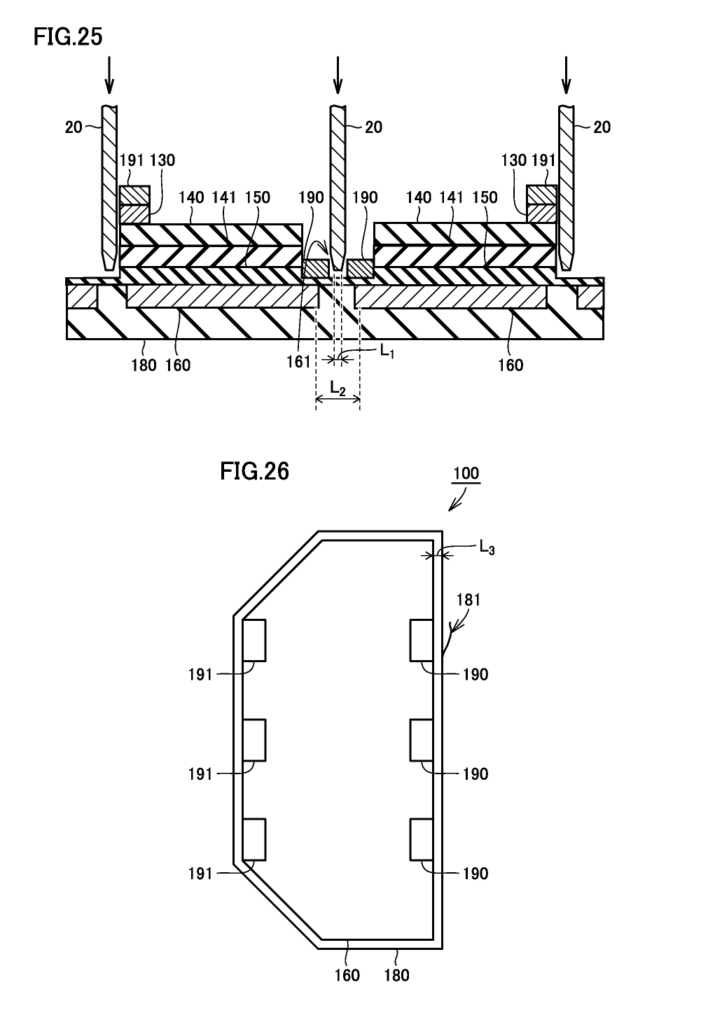

FIG. 25 is a sectional view depicting a state in which the Thomson blade is pressed. FIG. 26 is a plan view depicting the structure of a separated photovoltaic cell of a thin-film compound photovoltaic cell. Incidentally, in FIG. 26, the photoelectric conversion layer is not depicted.

As depicted in FIG. 25, by performing cutting by pressing the Thomson blade 20 against the position of the groove 161, the separated photovoltaic cell 100 of the thin-film compound photovoltaic cell is obtained. The Thomson blade 20 has, at the tip thereof, a flat surface with a width of L₁. The width of the groove 161 of the rear surface electrode 160 is L₂, and L₂>L₁.

For example, the width L₁ is 30 μm or more but 50 μm or less. The width L₂ of the groove 161 is set at (L₁+100) μm, for example, with consideration given to the alignment accuracy of the Thomson blade 20 and the photovoltaic cell 100.

As depicted in FIG. 26, in plan view, the edge of the base material 180 is located outside the edge of the rear surface electrode 160 with space left therebetween and surrounds the entire perimeter of the rear surface electrode 160. The distance L₃ between the edge of the base material 180 and the edge of the rear surface electrode 160 changes depending on the alignment accuracy of the Thomson blade 20 and the photovoltaic cell 100.

For example, the distance L₃ is 5 μm or more but 1 mm or less. As described above, when the width L₂ of the groove 161 is (L₁+100) μm, if the alignment accuracy is high, the distance L₃ is approximately 50 μm.

The edge of the base material 180 is formed of a cut surface formed by the cutting performed by the Thomson blade 20. In this embodiment, the edge of the rear surface electrode 160 is formed of an etched surface of the rear surface electrode 160 on which the material thereof is etched and exposed. In the above-described modified example, the edge of the rear surface electrode 160 is formed of a depositional surface on which the material of the rear surface electrode 160 is evaporated and deposited.

As described above, when the photovoltaic cells 100 are separated from each other, cutting is performed such that only the base material 180 and the second contact layer 150 are cut and the rear surface electrode 160 is not cut. By doing so, if a thread-like portion 181 which is an imperfect cut portion appears at the edge of the photovoltaic cell 100 as depicted in FIG. 26, the thread-like portion 181 is formed only of part of the base material 180 and part of the second contact layer 150.

As a result, when a photovoltaic cell array is configured by connecting the photovoltaic cell 100 having the thread-like portion 181 to another photovoltaic cell 100 by the interconnector 10 as depicted in FIG. 1, it is possible to prevent a short circuit from occurring by the thread-like portion 181. Therefore, it is possible to prevent a short circuit from occurring by the thread-like portion 181 and stably produce an output of the photovoltaic cell array.

Incidentally, the second contact layer 150 is formed of crystal and has almost no ductility, and the second contact layer 150 in the portion cut by the Thomson blade 20 shattered into pieces and does not form a continuous crystal. Moreover, the adhesion between the second contact layer 150 and the base material 180 is not good as compared to the adhesion between the rear surface electrode 160 and the base material 180, and some of the pieces of the shattered second contact layer 150 easily come off from the base material 180 included in the thread-like portion 181. Furthermore, the electrical resistance in an in-plane direction of the second contact layer 150 is higher than the electrical resistance in a depth direction thereof. Therefore, there is little possibility of the occurrence of a short circuit by part of the second contact layer 150 included in the thread-like portion 181.

As described above, by preventing a short circuit of the photovoltaic cell 100, it is possible to enhance the yield of the photovoltaic cell 100 and increase productivity.

Incidentally, in the photovoltaic cell 100 according to this embodiment, in plan view, the rear surface electrode 160 is located inside the photoelectric conversion layer, but the configuration is not limited thereto. The rear surface electrode 160 simply has to be located in an area which is cut by the Thomson blade 20, and part of the rear surface electrode 160 may be located outside the photoelectric conversion layer.

It should be understood that the embodiment disclosed in the above description is merely an example in all respects and is not restrictive. The scope of the present invention is presented in the claims, not in the above description, and is meant to include the meanings equivalent to the claims and all the changes made in the scope of the present invention.

### REFERENCE SIGNS LIST

10 interconnector
20 Thomson blade
100 photovoltaic cell
110 substrate
111 reinforcing material
120 etching-stop layer
130 first contact layer
140 emitter layer
141 base layer
150 second contact layer
160 rear surface electrode
161 groove
170, 171, 171a, 172, 173, 174 resist
180 base material
181 thread-like portion
190 first surface electrode
191 second surface electrode

1. A thin-film compound photovoltaic cell comprising:
a base material formed of a thin film;
a rear surface electrode located on the base material;
a photoelectric conversion layer located on the rear surface electrode;
a first surface electrode that is located above the rear surface electrode, is electrically connected to the rear surface electrode, and has a first polarity; and
a second surface electrode that is located on the photoelectric conversion layer and has a second polarity different from the first polarity,
wherein
an edge of the base material is located outside an edge of the rear surface electrode with space left therebetween and surrounds an entire perimeter of the rear surface electrode in plan view.

2. The thin-film compound photovoltaic cell according to claim 1, wherein
the edge of the base material is formed of a cut surface.

3. The thin-film compound photovoltaic cell according to claim 1, wherein
the edge of the rear surface electrode is formed of an etched surface of the rear surface electrode on which a material thereof is etched and exposed or a depositional surface on which the material of the rear surface electrode is evaporated and deposited.

4. The thin-film compound photovoltaic cell according to claim 1, wherein
the base material is formed of a film resin.

5. The thin-film compound photovoltaic cell according to claim 4, wherein
the resin is polyimide.

6. The thin-film compound photovoltaic cell according to claim 2, wherein
the cut surface is a cut surface formed by cutting performed by a Thomson blade.

7. A method for manufacturing a thin-film compound photovoltaic cell, the method comprising:
a process of forming a photoelectric conversion layer on a substrate;
a process of forming, on the photoelectric conversion layer, a rear surface electrode on which patterning has been performed to have a groove;
a process of forming a base material formed of a thin film on the rear surface electrode on which patterning has been performed;
a process of removing the substrate after the process of forming the base material;
a process of forming a first surface electrode being electrically connected to the rear surface electrode and having a first polarity on a side where the photoelectric conversion layer is located when viewed from the rear surface electrode after the process of removing the substrate;
a process of forming a second surface electrode having a second polarity different from the first polarity on a side opposite to the side of the photoelectric conversion layer where the rear surface electrode is located after the process of forming the first surface electrode; and
a process of performing cutting in a position of the groove after the process of forming the second surface electrode.

8. The method for manufacturing a thin-film compound photovoltaic cell according to claim 7, wherein
in the cutting process, cutting is performed by pressing a Thomson blade against the position of the groove.

9. The method for manufacturing a thin-film compound photovoltaic cell according to claim 7, wherein
the process of forming the rear surface electrode on which patterning has been performed to have the groove includes a process of forming the rear surface electrode on the photoelectric conversion layer and a process of forming a resist on the rear surface electrode and performing etching.

10. The method for manufacturing a thin-film compound photovoltaic cell according to claim 7, wherein
the process of forming the rear surface electrode on which patterning has been performed to have the groove includes a process of forming a resist in a position in which the groove has to be formed on the photoelectric conversion layer, a process of evaporating a material of the rear surface electrode on the photoelectric conversion layer and the resist, and a process of removing both the resist and the material of the rear surface electrode, the material evaporated on the resist.
